(19) United States
(12) Patent Application Publication
(10) Pub. No.: US 2005/0167684 A1
(43) Pub. Date: Aug. 4, 2005

(54) Device and method for emitting output light using group IIB element selenide-based phosphor material

(76) Inventors: Janet Bee Yin Chua, Penang (MY); Azlida Ahmad, Penang (MY); Hwai Peng Choo, Penang (MY); Hisham Menkara, Mableton, GA (US); Christopher J. Summers, Dunwoody, GA (US)

Correspondence Address: AGILENT TECHNOLOGIES, INC.;Legal Department, DL429, Intellectual Property Administration, P.O. Box 7599, Loveland, CO, 80537-0599, US

(21) Appl. No.: 10/761,762

(22) Filed: Jan. 21, 2004

(51) Int. Cl. H01L 33/00

(52) U.S. Cl. 257/98

(57) ABSTRACT

A device and method for emitting output light utilizes Group IIB element Selenide-based phosphor material to convert some of the original light emitted s from a light source of the device to a longer wavelength light to change the optical spectrum the output light. Thus, the device and method can be used to produce white color light. The Group IIB element Selenide-based phosphor material is included in a wavelength-shifting region optically coupled to the light source, which may be a blue-green light emitting diode (LED) die.

### FIELD OF THE INVENTION

The invention relates generally to light emitting devices, and more particularly to a phosphor-converted light emitting device.

### BACKGROUND OF THE INVENTION

Conventional light sources, such as incandescent, halogen and fluorescent lamps, have not been significantly improved in the past twenty years. However, light emitting diode (“LEDs”) have been improved to a point with respect to operating efficiency where LEDs are now replacing the conventional light sources in traditional monochrome lighting applications, such as traffic signal lights and automotive taillights. This is due in part to the fact that LEDs have many advantages over conventional light sources. These advantages include longer operating life, lower power consumption, and smaller size.

LEDs are typically monochromatic semiconductor light sources, and are currently available in various colors from UV-blue to green, yellow and red. Due to the narrow-band emission characteristics, monochromatic LEDs cannot be directly used for “white” light applications. Rather, the output light of a monochromatic LED must be mixed with other light of one or more different wavelengths to produce white light. Two common approaches for producing white light using monochromatic LEDs include (1) packaging individual red, green and blue LEDs together so that light emitted from these LEDs are combined to produce white light and (2) introducing fluorescent material into a UV, blue or green LED so that some of the original light emitted by the semiconductor die of the LED is converted into longer wavelength light and combined with the original UV, blue or green light to produce white light.

Between these two approaches for producing white light using monochromatic LEDs, the second approach is generally preferred over the first approach. In contrast to the second approach, the first approach requires a more complex driving circuitry since the red, green and blue LEDs include semiconductor dies that have different operating voltages requirements. In addition to having different operating voltage requirements, the red, green and blue LEDs degrade differently over their operating lifetime, which makes color control over an extended period difficult using the first approach. Moreover, since only a single type of monochromatic LED is needed for the second approach, a more compact device can be made using the second approach that is simpler in construction and lower in manufacturing cost. Furthermore, the second approach may result in broader light emission, which would translate into white output light having higher color-rendering characteristics.

A concern with the second approach for producing white light is that the fluorescent material currently used to convert the original UV, blue or green light results in LEDs having less than desirable luminance efficiency and/or light output stability over time.

In view of this concern, there is a need for an LED and method for emitting white output light using a fluorescent phosphor material with high luminance efficiency and good light output stability.

### SUMMARY OF THE INVENTION

A device and method for emitting output light utilizes Group IIB element Selenide-based phosphor material to convert some of the original light emitted from a light source of the device to a longer wavelength light to change the optical spectrum the output light. Thus, the device and method can be used to produce white color light. The Group IIB element Selenide-based phosphor material is included in a wavelength-shifting region optically coupled to the light source, which may be a blue-green light emitting diode (LED) die.

A device for emitting output light in accordance with an embodiment of the invention includes a light source that emits first light of a first peak wavelength in the 481-520 nm range and a wavelength-shifting region optically coupled to the light source to receive the first light. The wavelength-shifting region includes Group IIB element Selenide-based phosphor material having a property to convert some of the first light to second light of a second peak wavelength in the red wavelength range. The first light and the second light are components of the output light.

A method for emitting output light in accordance with an embodiment of the invention includes generating first light of a first peak wavelength in the 481-520 nm range, receiving the first light, including converting some of the first light to second light of a second peak wavelength in the red wavelength range using Group IIB element Selenide-based phosphor material, and emitting the first light and the second light as components of the output light.

Other aspects and advantages of the present invention will become apparent from the following detailed description, taken in conjunction with the accompanying drawings, illustrated by way of example of the principles of the invention.

### BRIEF DESCRIPTION OF THE DRAWINGS

FIG. 1 is a diagram of a white phosphor-converted LED in accordance with an embodiment of the invention.

FIGS. 2A, 2B and 2C are diagrams of white phosphor-converted LEDs with alternative lamp configurations in accordance with an embodiment of the invention.

FIGS. 3A, 3B, 3C and 3D are diagrams of white phosphor-converted LEDs with a leadframe having a reflector cup in accordance with an alternative embodiment of the invention

FIGS. 4A and 4B show the optical spectra of white phosphor-converted LEDs with blue and green LED dies, respectively, in accordance with an embodiment of the invention.

FIG. 5 is a plot of luminance (lv) degradation over time for a white phosphor-converted LED in accordance with an embodiment of the invention.

FIG. 6 is a flow diagram of a method for emitting output light in accordance with an embodiment of the invention.

### DETAILED DESCRIPTION

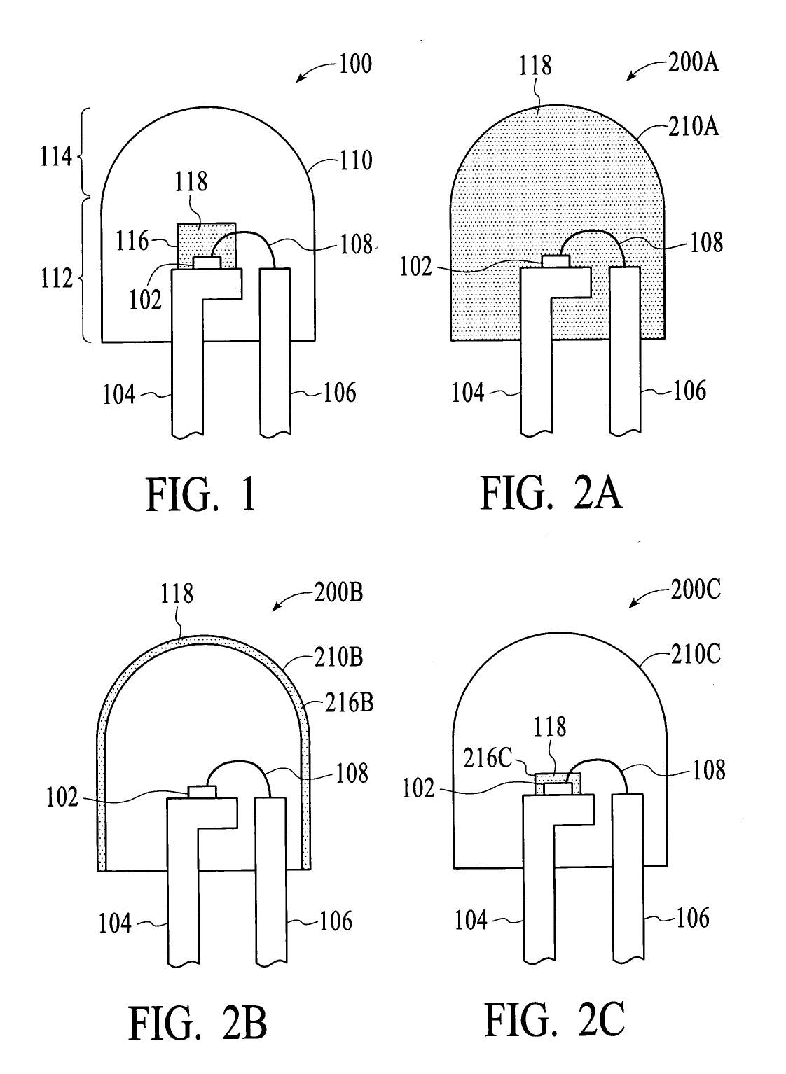

With reference to FIG. 1, a white phosphor-converted light emitting diode (LED) 100 in accordance with an embodiment of the invention is shown. The LED 100 is designed to produce “white” color output light with high luminance efficiency and good light output stability. The white output light is produced by converting some of the original light generated by the LED 100 into longer wavelength light using Group IIB element Selenide-based phosphor material. In an exemplary embodiment, the LED 100 includes only a single type of phosphor. Thus, in this embodiment, the LED 100 does not need a complex mixture of different phosphors, as is the case in some conventional white phosphor-converted LEDs.

As shown in FIG. 1, the white phosphor-converted LED 100 is a leadframe-mounted LED. The LED 100 includes an LED die 102, leadframes 104 and 106, a wire 108 and a lamp 110. The LED die 102 is a semiconductor chip that generates light of a particular peak wavelength. In the exemplary embodiment, the LED die 102 is designed to generate light having a peak wavelength in the 481-520 nm range, which lies in the blue-green region of the visible light spectrum. The LED die 102 is situated on the leadframe 104 and is electrically connected to the other leadframe 106 via the wire 108. The leadframes 104 and 106 provide the electrical power needed to drive the LED die 102. The LED die 102 is encapsulated in the lamp 110, which is a medium for the propagation of light from the LED die 102. The lamp 110 includes a main section 112 and an output section 114. In this embodiment, the output section 114 of the lamp 110 is dome-shaped to function as a lens. Thus, the light emitted from the LED 100 as output light is focused by the dome-shaped output section 114 of the lamp 110. However, in other embodiments, the output section 114 of the lamp 100 may be horizontally planar.

The lamp 110 of the white phosphor-converted LED 100 is made of a transparent substance, which can be any transparent material such as clear epoxy, so that light from the LED die 102 can travel through the lamp and be emitted out of the output section 114 of the lamp. In this embodiment, the lamp 110 includes a wavelength-shifting region 116, which is also a medium for propagating light, made of a mixture of the transparent substance and fluorescent phosphor material 118 based on Group IIB element Selenide. The Group IIB element Selenide-based phosphor material 118 is used to convert some of the original light emitted by the LED die 102 to lower energy (longer wavelength) light. The Group IIB element Selenide-based phosphor material 118 absorbs some of the original light from the LED die 102, which excites the atoms of the Group IIB element Selenide-based phosphor material, and emits the longer wavelength light. The peak wavelength of the converted light is partly defined by the peak wavelength of the original light and the Group IIB element Selenide-based phosphor material 118. The unabsorbed original light from the LED die 102 and the converted light are combined to produce “white” color light, which is emitted from the light output section 114 of the lamp 110 as output light of the LED 100. In the exemplary embodiment, the Group IIB element Selenide-based phosphor material 118 has a property to convert some of the original light from the LED die 102 into light of a longer peak wavelength in the red wavelength range of the visible spectrum, which is approximately 620 nm to 800 nm.

In one embodiment, the Group IIB element Selenide-based phosphor material 118 included in the wavelength-shifting region 116 of the lamp 110 is phosphor made of Zinc Selenide (ZnSe) activated by suitable dopant, such as Copper (Cu), Chlorine (Cl), Fluorine (F), Bromine (Br) and Silver (Ag). In an exemplary embodiment, the Group IIB element Selenide-based phosphor material 118 is phosphor made of ZnSe activated by Cu, i.e., ZnSe:Cu. Unlike conventional fluorescent phosphor materials that are used for producing white color light using LEDs, such as those based on alumina, oxide, sulfide, phosphate and halophosphate, ZnSe:Cu phosphor is highly efficient with respect to the wavelength-shifting conversion of light emitted from an LED die. This is due to the fact that most conventional fluorescent phosphor materials have a large bandgap, which prevents the phosphor materials from efficiently absorbing and converting light, e.g., blue-green light, to longer wavelength light. In contrast, the ZnSe:Cu phosphor has a lower bandgap, which equates to a higher efficiency with respect to wavelength-shifting conversion via fluorescence.

The ZnSe-based phosphor is the preferred Group IIB element Selenide-based phosphor material 118 for the wavelength-shifting region 116 of the lamp 110. However, the Group IIB element Selenide-based phosphor material 1 18 of the wavelength-shifting region 116 may be phosphor made of Cadmium Selenide (CdSe) activated by suitable dopant, such as Cu, Cl, F, Br and Ag. Alternatively, the Group IIB element Selenide-based phosphor material 118 of the wavelength-shifting region 116 may include a combination of ZnSe and CdSe activated by one or more suitable dopants.

The preferred ZnSe:Cu phosphor can be synthesized by various techniques. One technique involves dry-milling a predefined amount of undoped ZnSe material into fine powders or crystals, which may be less than 5 μm. A small amount of Cu dopant is then added to a solution from the alcohol family, such as methanol, and ball-milled with the undoped ZnSe powders. The amount of Cu dopant added to the solution can be anywhere between a minimal amount to approximately six percent of the total weight of ZnSe material and Cu dopant. The doped material is then oven-dried at around one hundred degrees Celsius (100° C.), and the resulting cake is dry-milled again to produce small particles. The milled material is loaded into a crucible, such as a quartz crucible, and sintered in an inert atmosphere at around one thousand degrees Celsius (1,000° C.) for one to two hours. The sintered materials can then be sieved, if necessary, to produce ZnSe:Cu phosphor powders with desired particle size distribution, which may be in the micron range.

Following the completion of the synthesis process, the ZnSe:Cu phosphor powders can be mixed with the same transparent substance of the lamp 110, e.g., epoxy, and deposited around the LED die 102 to form the wavelength-shifting region 116 of the lamp. The remaining part of the lamp 110 can be formed by depositing the transparent substance without the ZnSe:Cu phosphor powders to produce the white phosphor-converted LED 100. Although the wavelength-shifting region 116 of the lamp 110 is shown in FIG. 1 as being rectangular in shape, the wavelength-shifting region may be configured in other shapes, such as a hemisphere. Furthermore, in other embodiments, the wavelength-shifting region 116 may not be physically coupled to the LED die 102. Thus, in these embodiments, the wavelength-shifting region 116 may be positioned elsewhere within the lamp 10.

In FIGS. 2A, 2B and 2C, white phosphor-converted LEDs 200A, 200B and 200C with alternative lamp configurations in accordance with an embodiment of the invention are shown. The white phosphor-converted LED 200A of FIG. 2A includes a lamp 210A in which the entire lamp is a wavelength-shifting region. Thus, in this configuration, the entire lamp 200A is made of the mixture of the transparent substance and the Group IIB element Selenide-based phosphor material 118. The white phosphor-converted LED 200B of FIG. 2B includes a lamp 210B in which a wavelength-shifting region 216B is located at the outer surface of the lamp. Thus, in this configuration, the region of the lamp 210B without the Group IIB element Selenide-based phosphor material 118 is first formed over the LED die 102 and then the mixture of the transparent substance and the Group IIB element Selenide-based phosphor material 118 is deposited over this region to form the wavelength-shifting region 216B of the lamp. The white phosphor-converted LED 200C of FIG. 2C includes a lamp 210C in which a wavelength-shifting region 216C is a thin layer of the mixture of the transparent substance and the Group IIB element Selenide-based phosphor material 118 coated over the LED die 102. Thus, in this configuration, the LED die 102 is first coated or covered with the mixture of the transparent substance and the Group IIB element Selenide-based phosphor material 118 to form the wavelength-shifting region 216C and then the remaining part of the lamp 210C can be formed by depositing the transparent substance without the phosphor material over the wavelength-shifting region. As an example, the thickness of the wavelength-shifting region 216C of the LED 200C can be between ten (10) and sixty (60) microns, depending on the color of the light generated by the LED die 102.

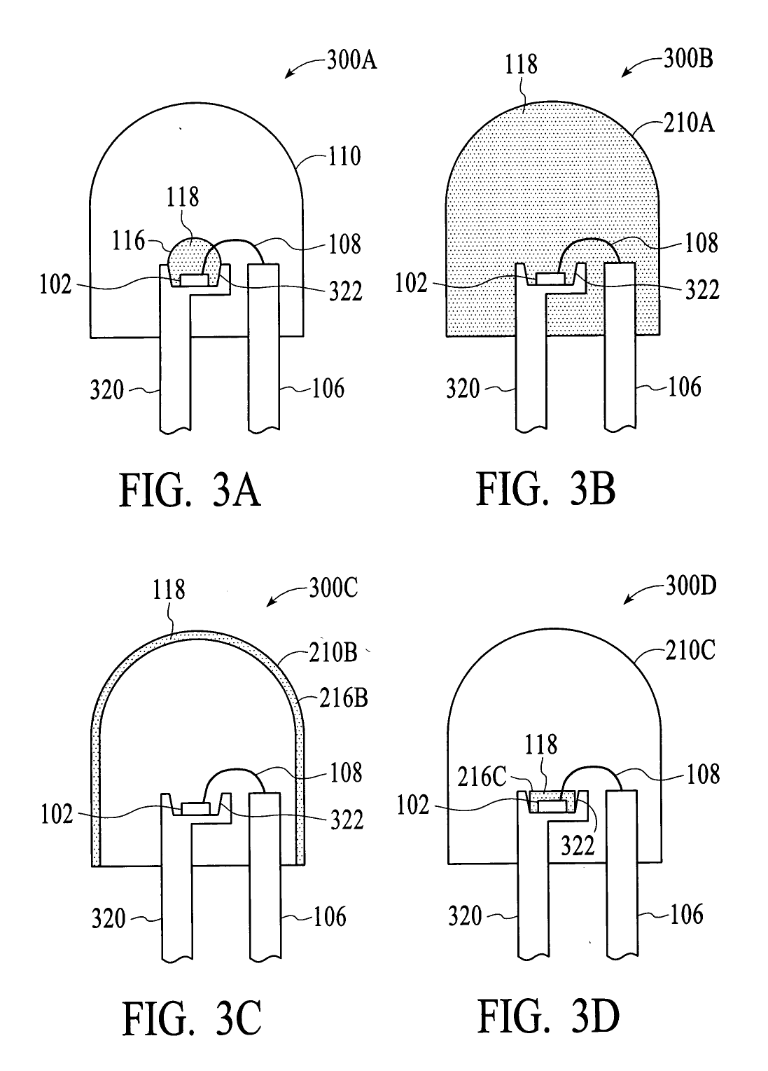

In an alternative embodiment, the leadframe of a white phosphor-converted LED on which the LED die is positioned may include a reflector cup, as illustrated in FIGS. 3A, 3B, 3C and 3D. FIGS. 3A-3D show white phosphor-converted LEDs 300A, 300B, 300C and 300D with different lamp configurations that include a leadframe 320 having a reflector cup 322. The reflector cup 322 provides a depressed region for the LED die 102 to be positioned so that some of the light generated by the LED die is reflected away from the leadframe 320 to be emitted from the respective LED as useful output light.

The different lamp configurations described above can be applied other types of LEDs, such as surface-mounted LEDs, to produce other types of white phosphor-converted LEDs with Group IIB element Selenide-based phosphor material in accordance with the invention. In addition, these different lamp configurations may be applied to other types of light emitting devices, such as semiconductor lasing devices, to produce other types of light emitting device in accordance with the invention.

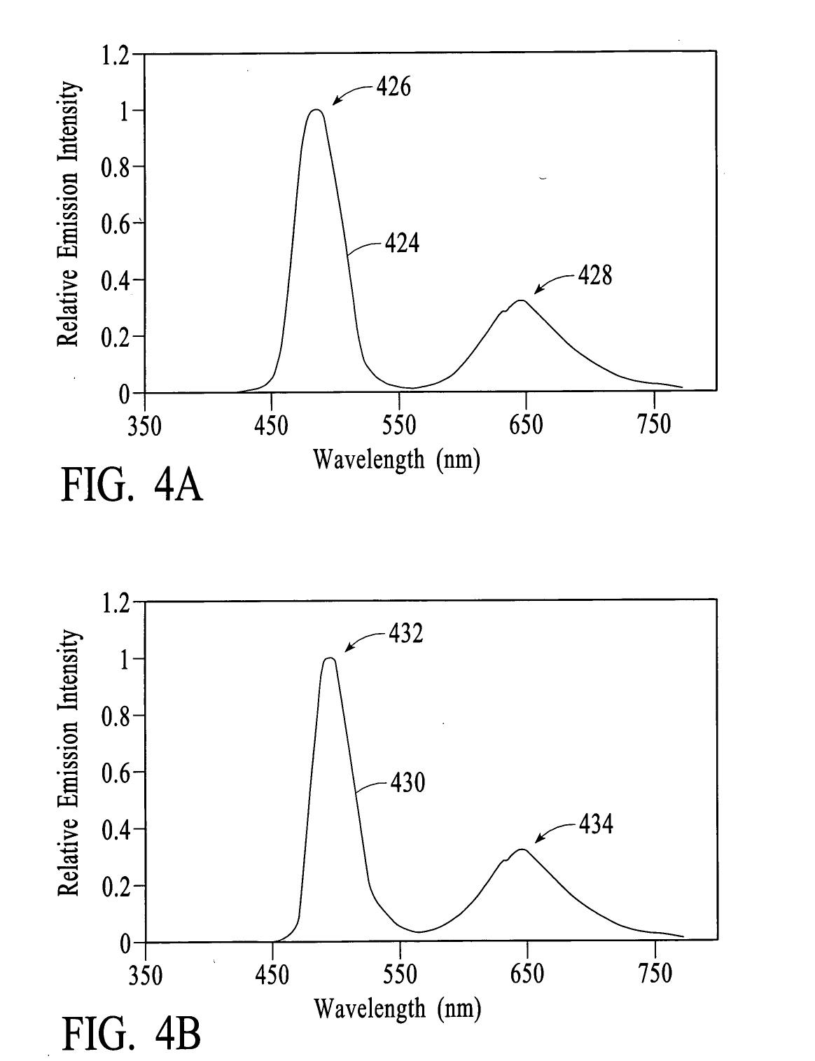

Turning now to FIG. 4A, the optical spectrum 424 of a white phosphor-converted LED with a blue LED die in accordance with an embodiment of the invention is shown. The wavelength-shifting region for this LED was formed with forty percent (40%) of ZnSe:Cu phosphor relative to epoxy. The percentage amount or loading content of ZnSe:Cu phosphor included in the wavelength-shifting region of the LED can be varied according to phosphor efficiency. As the phosphor efficiency is increased, e.g., by changing the amount of dopant, the loading content of the phosphor may be reduced. The optical spectrum 424 includes a first peak wavelength 426 at around 480 nm, which corresponds to the peak wavelength of the light emitted from the blue LED die, and a second peak wavelength 428 at around 650 nm, which is the peak wavelength of the light converted by the ZnSe:Cu phosphor in the wavelength-shifting region of the LED. Similarly, in FIG. 4B, the optical spectrum 430 of a white phosphor-converted LED with a green LED die in accordance with an embodiment of the invention is shown. The wavelength-shifting region for this LED was formed with forty-five percent (45%) of ZnSe:Cu phosphor relative to epoxy. The optical spectrum 430 includes a first peak wavelength 432 at around 494 nm, which corresponds to the peak wavelength of the light emitted from the green LED die, and a second peak wavelength 434 again at around 650 nm, which is the peak wavelength of the light converted by the ZnSe:Cu phosphor in the wavelength-shifting region of this LED. Thus, light of different peak wavelengths can be wavelength-shifted to around the same peak wavelength by adjusting the relative amount of ZnSe:Cu phosphor included in the wavelength-shifting region of an LED.

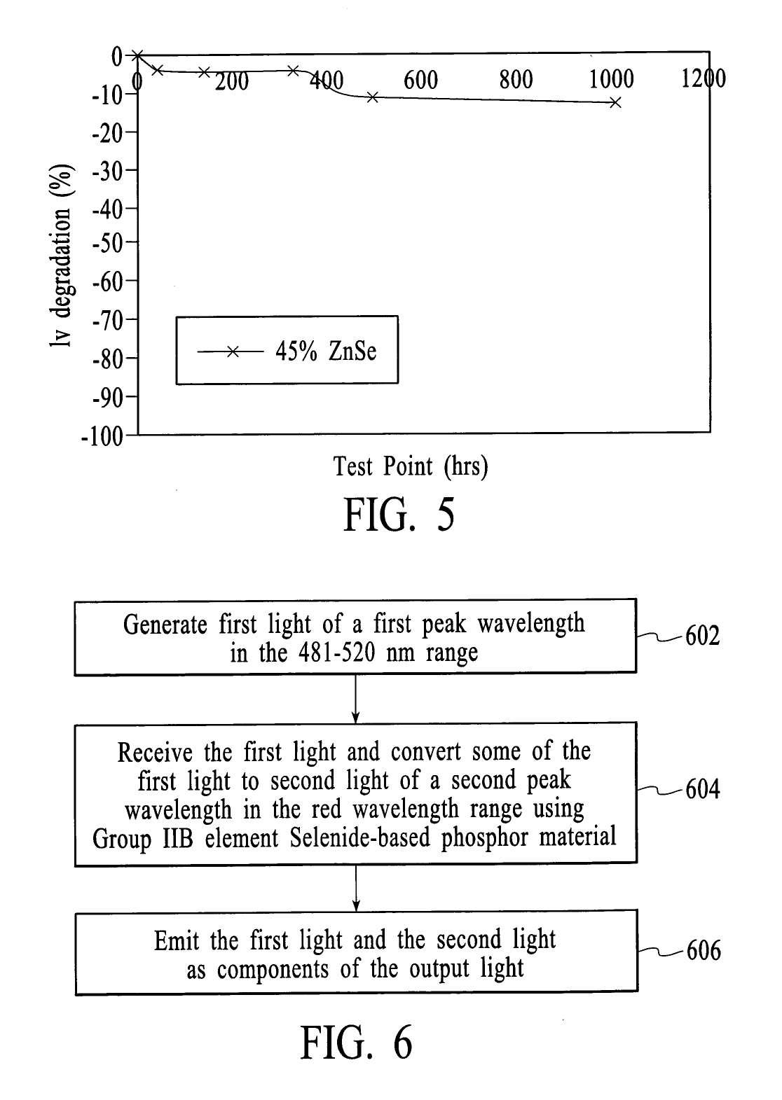

FIG. 5 is a plot of luminance (lv) degradation over time for a white phosphor-converted LED having a wavelength-shifting region with forty-five percent (45%) of ZnSe:Cu phosphor relative to epoxy in accordance with an embodiment of the invention. As illustrated by the plot of FIG. 5, the luminance properties of the white phosphor-converted LED experience little change over an extended period of time while being exposed to high intensity light, i.e., the light emitted from the semiconductor die of the LED. Thus, the ZnSe:Cu phosphor used in the LED has good resistance against light. This resistance to light is not limited to the light emitted from the semiconductor die of an LED, but also any external light, such as sunlight including ultraviolet light. Thus, LEDs in accordance with the invention are suitable for outdoor use, and can provide stable luminance over time with minimal color shift. In addition, these LEDs can be used in applications that require high response speeds since the duration of afterglow for the ZnSe:Cu phosphor is short.

A method for producing white output light in accordance with an embodiment of the invention is described with reference to FIG. 6. At block 602, first light of a first peak wavelength in the 481-520 nm range is generated. The first light may be generated by an LED die, such as a blue-green LED die. Next, at block 604, the first light is received and some of the first light is converted to second light of a second peak wavelength in the red wavelength range using Group IIB element Selenide-based phosphor material. Next, at block 606, the first light and the second light are emitted as components of the output light.

Although specific embodiments of the invention have been described and illustrated, the invention is not to be limited to the specific forms or arrangements of parts so described and illustrated. The scope of the invention is to be defined by the claims appended hereto and their equivalents.

1. A device for emitting output light, said device comprising:
a semiconductor chip that emits first light of a first peak wavelength in a 481-520 nm range; and
a wavelength-shifting region optically coupled to said semiconductor chip to receive said first light, said wavelength-shifting region including Group IIB element Selenide-based phosphor material having a property to convert some of said first light to second light of a second peak wavelength in a red wavelength range, said Group IIB element Selenide-based phosphor material including Group IIB clement Selenide activated by at least one element selected from a group consisting of Copper, Chloride, Fluorine, Bromine and Silver, said first light and said second light being components of said output light.

2. The device of claim 1 wherein said Group IIB element Selenide-based phosphor material of said wavelength-shifting region includes Zinc Selenide.

3. The device of claim 2 wherein said Group IIB element Selenide-based phosphor material of said wavelength-shifting region includes said Zinc Selenide activated by Copper.

4. The device of claim 1 wherein said Group IIB element Selenide-based phosphor material of said wavelength-shifting region includes Cadmium Selenide.

5. The device of claim 1 wherein said semiconductor chip is a light emitting diode die that can generate said first light of said first peak wavelength.

6. The device of claim 1 wherein said wavelength-shifting region is a part of a lamp coupled to said semiconductor chip.

7. The device of claim 1 wherein said wavelength-shifting region is a lamp coupled to said semiconductor chip.

8. A device for emitting output light, said device comprising:
a semiconductor die that emits first light of a first peak wavelength in a 481-520 nm range; and
a phosphor-containing medium positioned to receive said first light, said phosphor-containing medium including Group IIB element Selenide-based phosphor material having a property to convert some of said first light to second light of a second peak wavelength in a red wavelength range, said Group IIB element Selenide-based phosphor material including Group IIB element Selenide activated by oat least one element selected from a group consisting of Copper, Chlorine, Fluorine, Bromine and Silver, said first light and said second light being components of said output light.

9. The device of claim 8 wherein said Group IIB element Selenide-based phosphor material of said phosphor-containing medium includes Zinc Selenide.

10. The device of claim 9 wherein said Group IIB element Selenide-based phosphor material of said phosphor-containing medium includes said Zinc Selenide activated by Copper.

11. The device of claim 8 wherein said Group IIB element Selenide-based phosphor material of said phosphor-containing medium includes Cadmium Selenide.

12. The device of claim 8 wherein said semiconductor die is a light emitting diode die.

13. The device of claim 8 wherein said phosphor-containing medium is a part of a lamp coupled to said semiconductor die.

14. The device of claim 8 wherein said phosphor-containing medium is a lamp coupled to said semiconductor die.

15. A method for emitting output light, said method comprising:
generating first light of a first peak wavelength in a 481-520 nm range at a semiconductor die, including emitting said first light out of said semiconductor die;
receiving said first light emitted out of said semiconductor die, including converting some of said first light to second light of a second peak wavelength in a red wavelength range using Group IIB element Selenide-based phosphor material, said Group IIB element Selenide-based phosphor material including Group IIB element Selenide activated by at least one element selected from a group consisting of Copper, Chlorine, Fluorine, Bromine and Silver; and
emitting said first light and said second light as components of said output light.

16. The method of claim 15 wherein said Group IIB element Selenide-based phosphor material includes Zinc Selenide.

17. The method of claim 16 wherein said Group IIB element Selenide-based phosphor material includes said Zinc Selenide activated by Copper.

18. The method of claim 15 wherein said Group IIB element Selenide-based phosphor material includes Cadmium Selenide.

19. The method of claim 15 wherein said generating includes generating said first light of said first peak wavelength at a light emitting diode die.

20. The method of claim 19 wherein said light emitting diode die is configured to generate said first light such that said first peak wavelength is within a blue-green region of the visible light spectrum.
